(19) United States
(12) Patent Application Publication
(10) Pub. No.: US 2026/0223355 A1
(43) Pub. Date: Jul. 30, 2026

(54) SEMICONDUCTOR MEMORY DEVICE

(71) Applicant: Samsung Electronics Co., Ltd., Suwon-si (KR)

(72) Inventors: Yu Jin KIM, Suwon-si (KR); Jin Woo HAN, Suwon-si (KR); Ju Hyun KIM, Suwon-si (KR); Hyeon Cheol KIM, Suwon-si (KR)

(21) Appl. No.: 19/459,057

(22) Filed: Jan. 26, 2026

(30) Foreign Application Priority Data
Jan. 24, 2025 (KR) 10-2025-0011339

(51) Int. Cl. H10B 12/00

(52) U.S. Cl. CPC H10B 12/30

(57) ABSTRACT

A semiconductor device including memory cells arranged three-dimensionally. The semiconductor device includes a plurality of cell areas comprising a plurality of conductive patterns, the plurality of cell areas two-dimensionally arranged along a first direction and a second direction, each cell area of the plurality of cell areas including a conductive pattern of the plurality of conductive patterns; and a plurality of pad patterns respectively connected to the plurality of conductive patterns. For each cell area, a first cell pitch is greater than a second cell pitch. Each pad pattern has a quadrangle shape including a first side and a second side intersecting each other. For each pad pattern, a length of the first side and a length of the second side are both greater than the second cell pitch, and for each pad pattern, the angle between the first side and the first direction is an acute angle.

### CROSS-REFERENCE TO RELATED APPLICATION

This application claims priority from Korean Patent Application No. 10-2025-0011339 filed on Jan. 24, 2025, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor memory device. More specifically, the present disclosure relates to a semiconductor memory device including memory cells arranged three-dimensionally.

### Description of Related Art

As a semiconductor memory device capable of storing high-capacity data therein in an electronic system is required, schemes for increasing a data storage capacity of the semiconductor memory device are being studied. In one of the schemes for increasing the data storage capacity of the semiconductor memory device, a semiconductor memory device including memory cells arranged three-dimensionally instead of memory cells arranged two-dimensionally has been proposed.

### SUMMARY

A technical purpose to be achieved by the present disclosure is to provide a semiconductor memory device with an improved process margin.

The technical purposes of the present disclosure are not limited to the technical purposes mentioned above, and other technical purposes not mentioned may be clearly understood by those skilled in the art from the following description.

According to an aspect of the present disclosure, there is provided a semiconductor memory device comprising a plurality of cell areas comprising a plurality of conductive patterns, the plurality of cell areas two-dimensionally arranged along a first direction and a second direction intersecting each other, each cell area of the plurality of cell areas including a conductive pattern of the plurality of conductive patterns extending in a third direction intersecting the first direction and the second direction, and a plurality of pad patterns respectively connected to the plurality of conductive patterns, wherein in a plan view intersecting the third direction, for each cell area of the plurality of cell areas, a first cell pitch in the first direction is greater than a second cell pitch in the second direction, wherein in the plan view, each pad pattern of the plurality of pad patterns has a quadrangle shape including a first side and a second side intersecting each other, wherein in the plan view a length of the first side and a length of the second side are both greater than the second cell pitch, and wherein in the plan view, for each pad pattern of the plurality of pad patterns the angle between the first side and the first direction is an acute angle.

According to an aspect of the present disclosure, there is provided a semiconductor memory device comprising a plurality of cell areas two-dimensionally arranged along a first direction and a second direction intersecting each other, a plurality of strap patterns on the plurality of cell areas, each strap pattern of the plurality of strap patterns extending in the first direction, and a plurality of pad patterns on the plurality of strap patterns, the plurality of pad patterns respectively connected to the plurality of strap patterns, wherein each cell area of the plurality of cell areas includes: a plurality of unit memory cells arranged in a third direction intersecting the first direction and the second direction, and a conductive pattern extending in the third direction and being connected commonly to the plurality of unit memory cells in the cell area, wherein each strap pattern of the plurality of strap patterns connects n conductive patterns arranged along the first direction to each other, where n is a natural number of 2 or greater, wherein each pad pattern of the plurality of pad patterns has a square shape in a plan view intersecting the third direction, and wherein for each pad pattern of the plurality of pad patterns, the angle between one side of the pad pattern and the first direction is an acute angle.

According to an aspect of the present disclosure, there is provided a semiconductor memory device comprising a first substrate including a first surface and a second surface opposite to each other, a plurality of cell areas on the first surface, the plurality of cell areas including a plurality of conductive patterns and two-dimensionally arranged along a first direction and a second direction parallel to the first surface and intersecting each other, and each cell area of the plurality of cell areas includes a conductive pattern of the plurality of conductive patterns, and the conductive pattern extending in a third direction intersecting the first direction and the second direction, a plurality of pad patterns on the plurality of cell areas, the plurality of pad patterns respectively connected to the plurality of conductive patterns, a second substrate including a third surface facing the first surface and a fourth surface opposite to the third surface, and a peripheral circuit element layer disposed on the third surface, wherein each cell of the plurality of cell areas includes a plurality of unit memory cells arranged in the third direction, wherein each unit memory cell of the plurality of unit memory cells includes: a semiconductor pattern extending in the first direction and connected to the conductive pattern of the cell area, a data storage structure connected to the semiconductor pattern, and a gate electrode extending in the second direction, the gate electrode intersecting the semiconductor pattern between the conductive pattern of the cell area and the data storage structure, wherein each pad pattern of the plurality of pad patterns has a square shape in a plan view intersecting the third direction, and wherein for each pad pattern of the plurality of pad patterns, the angle between one side the pad pattern and the first direction is an acute angle.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is an example block diagram illustrating a semiconductor memory device according to some embodiments.

FIG. 2 is a schematic perspective view illustrating the semiconductor memory device according to some embodiments.

FIG. 3 is a schematic plan view illustrating a semiconductor memory device according to some embodiments.

FIG. 4 is a perspective view illustrating each of unit cell areas of FIG. 3.

FIG. 5 is an example plan view illustrating pad patterns of a semiconductor memory device according to some embodiments.

FIG. 6 is an example perspective view illustrating pad patterns of a semiconductor memory device according to some embodiments.

FIG. 7 is an example plan view illustrating pad patterns of a semiconductor memory device according to some embodiments.

FIG. 8 is an example perspective view illustrating pad patterns of a semiconductor memory device according to some embodiments.

### DETAILED DESCRIPTIONS

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. Items described in the singular herein may be provided in plural, as can be seen, for example, in the drawings. Thus, the description of a single item that is provided in plural should be understood to be applicable to the remaining plurality of items unless context indicates otherwise. The language of the claims should be referenced in determining the requirements of the invention.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be conducted from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

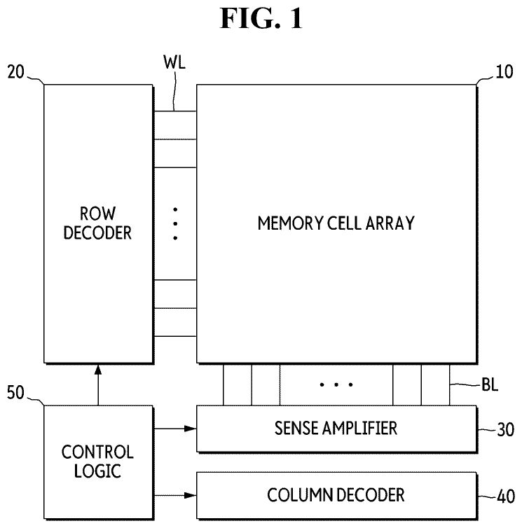

Hereinafter, a semiconductor memory device according to example embodiments will be described with reference to FIGS. 1 to 8.

FIG. 1 is an example block diagram for illustrating a semiconductor memory device according to some embodiments.

Referring to FIG. 1, the semiconductor memory device according to some embodiments includes a memory cell array 10, a row decoder 20, a sense amplifier 30, a column decoder 40, and a control logic 50.

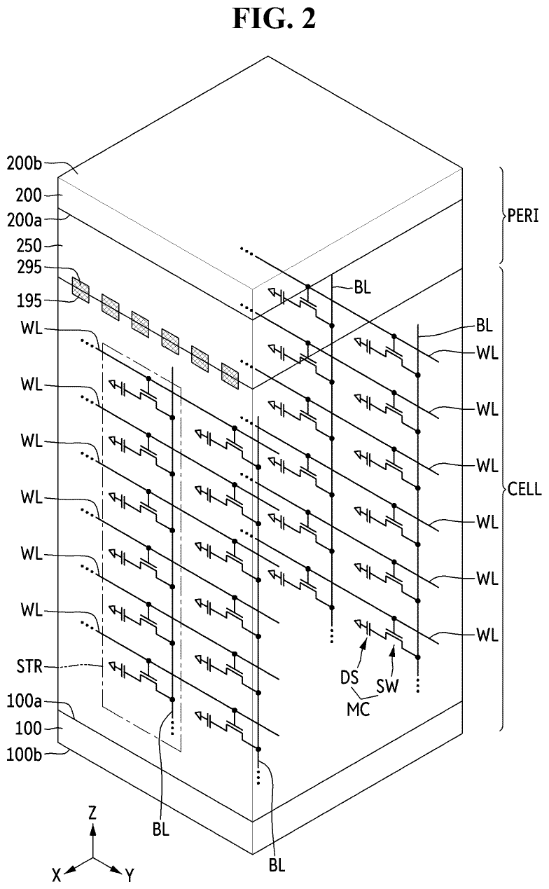

The memory cell array 10 may include a plurality of memory cells (e.g., MC of FIG. 2) that are three-dimensionally arranged. The memory cell array 10 may be connected to the row decoder 20 via a plurality of word lines WL. In addition, the memory cell array 10 may be connected to the sense amplifier 30 via a plurality of bit lines BL.

The row decoder 20 may decode an address input from an external source to select one of the plurality of word lines WL connected to the memory cell array 10. The address decoded by the row decoder 20 may be provided to a row driver (not shown). The row driver may provide a predetermined voltage to each of the selected word line WL and an unselected word line WL in response to control of the control circuits.

The sense amplifier 30 may sense, amplify, and output a voltage change of the selected bit line BL among the plurality of bit lines WL based on the address decoded from the column decoder 40. For example, the sense amplifier 30 may sense, amplify, and output a difference between voltages of the selected bit line BL and a reference bit line.

The column decoder 40 may provide a data transmission path between the sense amplifier 30 and an external device (e.g., a memory controller). The column decoder 40 may decode the address input from an external source and select one of the plurality of word lines WL based on the decoded address.

The control logic 50 may generate control signals for controlling a write operation and/or a read operation on each of the memory cells of the memory cell array 10.

FIG. 2 is a schematic perspective view illustrating the semiconductor memory device according to some embodiments.

Referring to FIGS. 1 and 2, the semiconductor memory device according to some embodiments includes a memory cell structure CELL and a peripheral circuit structure PERI.

The memory cell structure CELL may include a first substrate 100 and a plurality of memory cells MC on the first substrate 100.

The first substrate 100 may be made of bulk silicon or silicon-on-insulator (SOI). The first substrate 100 may be a silicon substrate, or may include a material other than silicon, for example, silicon germanium, gallium arsenide, silicon germanium on insulator (SGOI), indium antimonide, lead telluride compound, indium arsenide, indium phosphide, gallium arsenide, or gallium antimonide. Alternatively, the first substrate 100 may include a base substrate and an epitaxial layer formed on the base substrate, or may include a ceramic substrate, a quartz substrate, a glass substrate for display, or the like.

The first substrate 100 may include a first surface 100a and a second surface 100b opposite to each other. In following descriptions, the first surface 100a may also be referred to as a frontside or a front surface of the first substrate 100, and the second surface 100b may also be referred to as a backside or a back surface or a rear surface of the first substrate 100.

The plurality of memory cells MC may be formed on the first surface 100a of the first substrate 100. The plurality of memory cells MC may be three-dimensionally arranged. For example, a plurality of cell strings STR, which are two-dimensionally arranged along a first direction X and a second direction Y, which are parallel to an upper surface (e.g., the first surface 100a) of the first substrate 100 and intersect with each other, may be formed on the first substrate 100. Each of the cell strings STR may include a plurality of memory cells MC arranged along a third direction Z intersecting the upper surface of the first substrate 100 (e.g., the first surface 100a).

Each of the memory cells MC may be connected to and disposed between a word line WL and a bit line BL intersecting with each other. For example, each of the word lines WL may extend in the second direction Y and may be connected commonly to the memory cells MC arranged in the second direction Y. For example, each of the bit lines BL may extend in the third direction Z and may be connected commonly to the memory cells MC arranged in the third direction Z.

Each of the memory cells MC may include a select element SW and a data storage element DS connected in series with each other.

The select element SW may be connected to and disposed between the bit line BL and the data storage element DS. The select element SW may be configured to selectively control a flow of charges to be provided to the data storage element DS. For example, the select element SW may include at least one of a diode, a PNP bipolar transistor, a NPN bipolar transistor, a NMOS field effect transistor, a PMOS field effect transistor, or a combination thereof. In some embodiments, the select element SW may be a Field Effect Transistor (FET). For example, a gate of the select element SW may be connected to the word line WL, and a source and a drain of the select element SW may be connected to the bit line BL and the data storage element DS, respectively.

The data storage element DS may be controlled by the word line WL and the bit line BL so as to store data in each of the memory cells MC. For example, the data storage element DS may include a capacitor and/or a variable resistor. In some embodiments, each of the memory cells MC may be a unit memory cell of a dynamic random access memory (DRAM). For example, the data storage element DS may be a capacitor.

The peripheral circuit structure PERI may include a second substrate 200 and a peripheral circuit element layer 250 on the second substrate 200.

The second substrate 200 may include, for example, a semiconductor substrate such as a silicon substrate, a germanium substrate, or a silicon-germanium substrate. Alternatively, the second substrate 200 may include a SOI (Silicon-On-Insulator) substrate or a GOI (Germanium-On-Insulator) substrate.

The second substrate 200 may include a third surface 200a and a fourth surface 200b opposite to each other. In following descriptions, the third surface 200a may also be referred to as a frontside or a front surface of the second substrate 200, and the fourth surface 200b may also be referred to as a backside or a back surface or a rear surface of the second substrate 200.

The peripheral circuit element layer 250 may be formed on the third surface 200a of the second substrate 200. The peripheral circuit element layer 250 may constitute a peripheral circuit that controls the operation of the semiconductor memory device. For example, the peripheral circuit element layer 250 may include a row decoder (e.g., 20 of FIG. 1), a sense amplifier (e.g., 30 of FIG. 1), a column decoder (e.g., 40 of FIG. 1), and/or a control logic (e.g., 50 of FIG. 1).

The peripheral circuit element layer 250 may include, for example, a transistor. However, the present disclosure is not limited thereto. For example, the peripheral circuit element layer 250 may include various passive elements such as a capacitor, a resistor, and an inductor, as well as various active elements such as transistors.

In some embodiments, the memory cell structure CELL and the peripheral circuit structure PERI may be stacked along the third direction Z.

The semiconductor memory device according to some embodiments may have a chip to chip (C2C) structure. The C2C structure means that a lower chip including the memory cell structure CELL is fabricated on a first wafer, an upper chip including the peripheral circuit structure PERI is fabricated on a second wafer different from the first wafer, and then the lower chip and the upper chip are connected to each other in a bonding manner.

For example, the bonding manner may refer to a scheme of connecting a first bonding metal 195 formed as the uppermost metal layer of the lower chip and a second bonding metal 295 formed as the uppermost metal layer of the upper chip to each other. For example, when each of the first bonding metal 195 and the second bonding metal 295 is made of copper (Cu), the bonding scheme may be a Cu—Cu bonding scheme. However, this is merely an example, and the first bonding metal 195 and the second bonding metal 295 may be made of various other metals such as aluminum (Al) or tungsten (W), respectively.

As the first bonding metal 195 and the second bonding metal 295 are bonded to each other, the memory cell structure CELL and the peripheral circuit structure PERI may be electrically connected to each other.

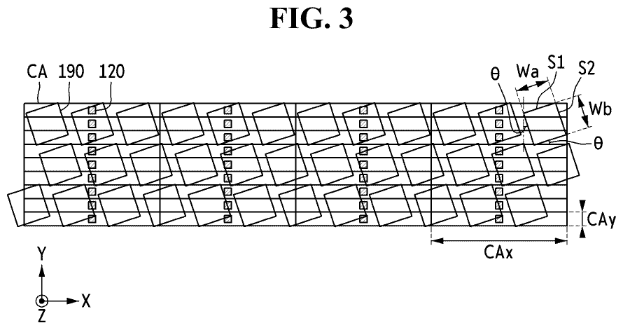

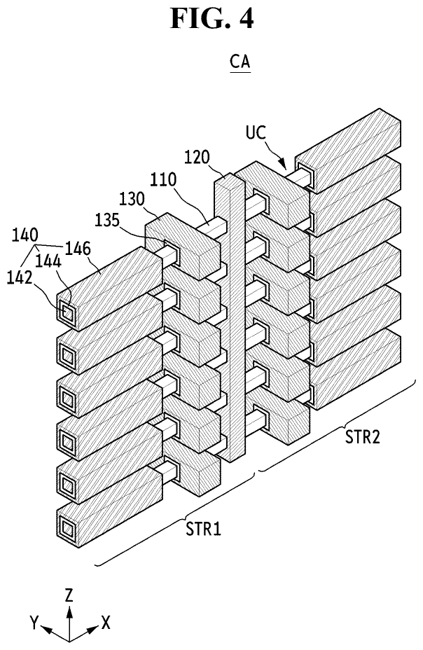

FIG. 3 is a schematic plan view for illustrating a semiconductor memory device according to some embodiments. FIG. 4 is a perspective view for illustrating each of unit cell areas of FIG. 3.

Referring to FIGS. 1 to 3, the semiconductor memory device according to some embodiments includes a plurality of cell areas CA and a plurality of pad patterns 190.

The plurality of cell areas CA may be two-dimensionally arranged along the first direction X and the second direction Y that intersect (e.g., are orthogonal to) each other. For example, the plurality of cell areas CA may be arranged in a lattice form along the first direction X and the second direction Y.

The plurality of cell areas CA may include a plurality of conductive patterns 120. Each of the plurality of conductive patterns 120 may extend in an elongate manner in the third direction Z intersecting (e.g., orthogonal to) the first direction X and the second direction Y. For example, as illustrated in FIG. 3, each of the cell areas CA may include one conductive pattern 120 extending in the third direction Z. In the semiconductor memory device according to some embodiments, each of the conductive patterns 120 may be provided as the bit line BL of FIGS. 1 and 2.

The plurality of pad patterns 190 may be formed on the plurality of cell areas CA. The plurality of pad patterns 190 may be spaced apart from each other. Each of the pad patterns 190 may be electrically connected to at least one of the conductive patterns 120. For example, as illustrated in FIG. 3, the plurality of pad patterns 190 corresponding to the plurality of conductive patterns 120 may be formed. In some embodiments, the number of the conductive patterns 120 and the number of the pad patterns 190 may have a 1:1 correspondence. In some embodiments, the number of the conductive patterns 120 and the number of the pad patterns 190 may have a correspondence relationship of n:1 (where n is a natural number of 2 or larger).

In some embodiments, each of the pad patterns 190 may be provided as the first bonding metal 195 of FIG. 2. However, the present disclosure is not limited thereto.

Each of the cell areas CA may have a first cell pitch CAx in the first direction X. The first cell pitch CAx may be defined, for example, as a spacing by which the cell areas CA are periodically arranged so as to be spaced from each other along the first direction X.

Each of the cell areas CA may have a second cell pitch CAy in the second direction Y. The second cell pitch CAy may be defined, for example, as a spacing by which the cell areas CA are periodically arranged so as to be spaced from each other along the second direction Y.

The first cell pitch CAx of each of the cell areas CA may be greater than the second cell pitch CAy of each of the cell areas CA. For example, the first cell pitch CAx may be two times or greater, five times or greater, or ten times or greater of the second cell pitch CAy. The first cell pitch CAx may be 100 times or smaller, 50 times or smaller, or 20 times or smaller of the second cell pitch CAy. However, the present disclosure is not limited thereto.

In a plan view intersecting the third direction Z (e.g., in the XY plane), each of the pad patterns 190 may include a first side S1 and a second side S2 intersecting each other. In some embodiments, each of the pad patterns 190 may have a quadrangular shape. In this regard, the quadrangular shape includes a quadrangular shape with rounded corners. For example, each of the pad patterns 190 may have a rectangular shape including a first side S1 and a second side S2 that are orthogonal to each other.

Each of a length Wa of the first side S1 and a length Wb of the second side S2 may be greater than the second cell pitch CAy. In some embodiments, each of the length Wa of the first side S1 and the length Wb of the second side S2 may be smaller than the first cell pitch CAx. In some embodiments, each of the pad patterns 190 may have a square shape. For example, the length Wa of the first side S1 and the length Wb of the second side S2 may be equal to each other.

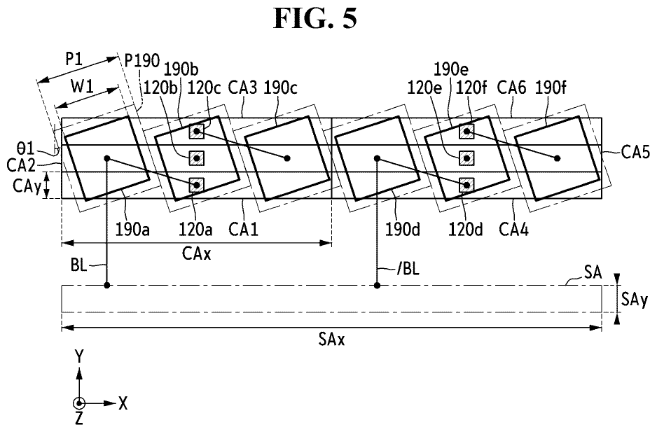

In a plan view intersecting the third direction Z (e.g., in the XY plane), each of the pad patterns 190 may have a shape rotated by a predetermined rotation angle θ with respect to the first direction X or the second direction Y. For example, the first side S1 of each of the pad patterns 190 may define a rotation angle θ that is an acute angle with respect to the first direction X. Alternatively, for example, the second side S2 of each of the pad patterns 190 may define a rotation angle θ, which is an acute angle with respect to the second direction Y. The rotation angle θ will be described in more detail later in the description using FIGS. 5 to 8.

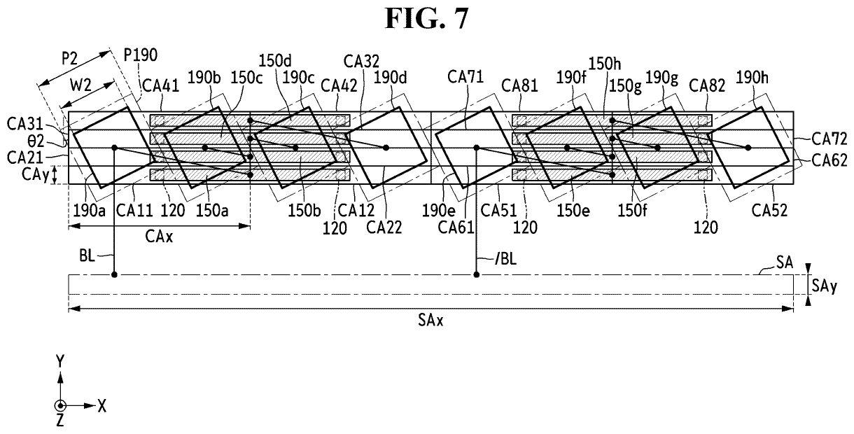

In some embodiments, each of the length Wa of the first side S1 and the length Wb of the second side S2 may be smaller than a pad pitch (e.g., P1 of FIG. 5 or P2 of FIG. 7) as a spacing by which the plurality of pad patterns 190 are periodically arranged to be spaced from each other. The pad pitch will be described in more detail later in the description using FIGS. 5 to 8.

Referring to FIGS. 1 to 4, in the semiconductor memory device according to some embodiments, each of the cell areas CA includes a plurality of unit memory cells UC arranged in the third direction Z.

The conductive pattern 120 of each of the cell areas CA may extend in the third direction Z and may be connected commonly to the plurality of unit memory cells UC. Each of the unit memory cells UC may include a semiconductor pattern 110, a gate electrode 130, a gate dielectric layer 135, and a data storage structure 140.

The semiconductor pattern 110 may extend in the first direction X. The semiconductor pattern 110 may connect the conductive pattern 120 and the data storage structure 140 to each other. For example, the conductive pattern 120 may contact a first portion of the semiconductor pattern 110, and the data storage structure 140 may contact a second portion of the semiconductor pattern 110. In the semiconductor memory device according to some embodiments, the first portion of the semiconductor pattern 110 and the second portion of the semiconductor pattern 110 may be provided as source/drain areas of the select element SW of FIG. 2, respectively.

Although the semiconductor pattern 110 is illustrated as having a rectangular pillar shape extending in the first direction X, this is only an example. Unlike the illustrated example, the semiconductor pattern 110 may have a cylindrical shape or another polygonal pillar shape.

The semiconductor pattern 110 may include a semiconductor material, for example, monocrystalline silicon, polycrystalline silicon (polysilicon), an organic semiconductor material, or a carbon nanostructure. However, the present disclosure is not limited thereto. For example, the semiconductor pattern 110 may include a single crystal silicon pattern.

The gate electrode 130 may extend in the second direction Y. The gate electrode 130 may intersect the semiconductor pattern 110 while being disposed between the conductive pattern 120 and the data storage structure 140. For example, the semiconductor pattern 110 may include a third portion between the first portion and the second portion. The gate electrode 130 may extend in the second direction Y so as to intersect the third portion of the semiconductor pattern 110.

The gate electrode 130 may include a conductive material, for example, a metal such as tungsten (W), molybdenum (Mo), ruthenium (Ru), cobalt (Co), nickel (Ni), or the like; and/or a semiconductor material such as silicon. However, the present disclosure is not limited thereto. In the semiconductor memory device according to some embodiments, the gate electrode 130 may be provided as a gate of the select element SW of FIG. 2.

In some embodiments, the gate electrode 130 may have a gate-all-around structure surrounding an outer surface of the semiconductor pattern 110. For example, the semiconductor pattern 110 may extend in the first direction X so as to extend through the gate electrode 130.

A gate dielectric film 135 may be interposed between the semiconductor pattern 110 and the gate electrode 130. The gate electrode 130 may be spaced apart from the semiconductor pattern 110 via the gate dielectric film 135. For example, the gate dielectric layer 135 may surround the third portion of the semiconductor pattern 110.

The gate dielectric film 135 may include, but is not limited to, at least one of silicon oxide, silicon nitride, silicon oxynitride, and a high-k material having a higher dielectric constant than that of silicon oxide. The high-k material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and combinations thereof.

The data storage structure 140 may be connected to the second portion of the semiconductor pattern 110. In the semiconductor memory device according to some embodiments, the data storage structure 140 may be provided as the data storage element DS of FIG. 2. The data storage structure 140 may be controlled by the gate electrode 130 provided as the word line WL and the conductive pattern 120 provided as the bit line BL to store data in each of the unit memory cells UC.

In some embodiments, the data storage structure 140 may include a capacitor. For example, the data storage structure 140 may include a first electrode 142, a capacitor dielectric film 144, and a second electrode 146. The first electrode 142 may extend in the first direction X. Although the first electrode 142 is illustrated as having a rectangular pillar shape extending in the first direction X, this is only an example. Unlike the illustrated case, the first electrode 142 may have a cylindrical shape or may have another polygonal cylindrical shape. The second electrode 146 may face the first electrode 142. For example, the second electrode 146 may surround an outer surface of the first electrode 142. The capacitor dielectric film 144 may be interposed between the first electrode 142 and the second electrode 146. For example, the capacitor dielectric film 144 may conformally extend along a profile of a surface of the first electrode 142. The first electrode 142 and the second electrode 146 may be spaced apart from each other via the capacitor dielectric film 144.

Each of the first electrode 142 and the second electrode 146 may include a conductive material, for example, doped polysilicon, a metal, or a metal nitride. However, the present disclosure is not limited thereto. The capacitor dielectric film 144 may include, for example, but is not limited to, at least one of silicon oxide, silicon nitride, silicon oxynitride, and the high-k dielectric material. The data storage structure 140 may store charges in the capacitor dielectric film 144 using a potential difference generated between the first electrode 142 and the second electrode 146.

In some embodiments, each of the cell areas CA may include a first cell string STR1 and a second cell string STR2 that share one conductive pattern 120 with each other. For example, in each of the cell areas CA, one conductive pattern 120 may be connected to and disposed between the first cell string STR1 and the second cell string STR2 in the first direction X. Each of the first and second cell strings STR1 and STR2 may include a plurality of unit memory cells UC arranged in the third direction Z.

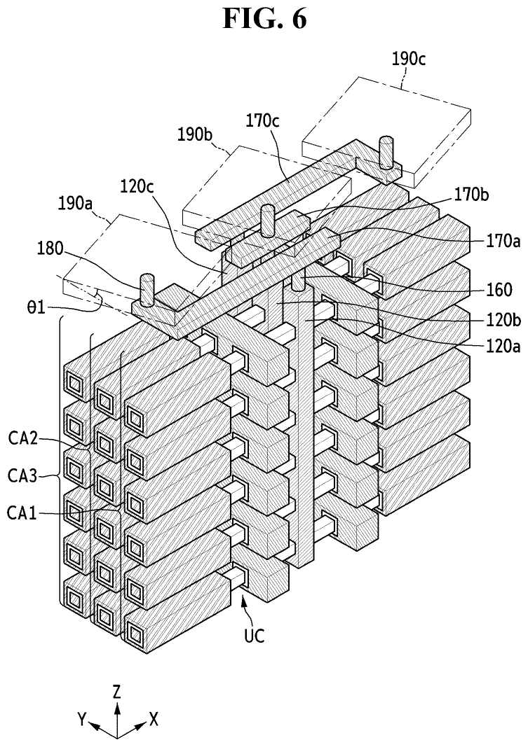

FIG. 5 is an example plan view for illustrating pad patterns of a semiconductor memory device according to some embodiments. FIG. 6 is an example perspective view for illustrating pad patterns of a semiconductor memory device according to some embodiments. For convenience of description, features described previously with reference to FIGS. 1 to 4 may be described briefly or descriptions thereof may be omitted.

Referring to FIGS. 5 and 6, the semiconductor memory device according to some embodiments may include first to sixth cell areas CA1 to CA6 and first to sixth pad patterns 190a to 190f.

The first to third cell areas CA1 to CA3 may be sequentially arranged along the second direction Y. The fourth to sixth cell areas CA4 to CA6 may be sequentially arranged along the second direction Y. The first and fourth cell areas CA1 and CA4 may be arranged along the first direction X, the second and fifth cell areas CA2 and CA5 may be arranged along the first direction X, and the third and sixth cell areas CA3 and CA6 may be arranged along the first direction X.

The first to sixth cell areas CA1 to CA6 may include first to sixth conductive patterns 120a to 120f, respectively. The first to sixth cell areas CA1 to CA6 may correspond to the cell area CA of FIGS. 3 and 4, respectively. For example, each of the first to sixth cell areas CA1 to CA6 may include the plurality of unit memory cells UC described above with reference to FIG. 4.

The first to sixth pad patterns 190a to 190f may be formed on the first to sixth cell areas CA1 to CA6. For example, the first to sixth pad patterns 190a to 190f may overlap the first to sixth cell areas CA1 to CA6 in the third direction Z.

The first to sixth pad patterns 190a to 190f may be spaced apart from each other. For example, a plurality of pad areas P190 corresponding to the first to sixth pad patterns 190a to 190f may be defined on the first to sixth cell areas CA1 to CA6. The plurality of pad areas P190 may have a 1:1 correspondence relationship with the first to sixth pad patterns 190a to 190f. The first to sixth pad patterns 190a to 190f may be respectively disposed in the plurality of pad areas P190 in the corresponding manner to each other. In a plan view intersecting the third direction Z (e.g., in the XY plane), each of the pad areas P190 may have a size larger than and a similar shape to a size and a shape of corresponding one of the first to sixth pad patterns 190a to 190f. For example, when each of the first to sixth pad patterns 190a to 190f has a square shape having each side of a first length W1, each of the pad areas P190 may have a square shape having each side of a first pad pitch P1 greater than the first length W1.

In a plan view intersecting the third direction Z (e.g., in the XY plane), each of the first to sixth pad patterns 190a to 190f may have a shape rotated by a predetermined first rotation angle θ1 with respect to the first direction X or the second direction Y. As each of the first to sixth pad patterns 190a to 190f has a shape rotated by the first rotation angle θ1, each of the corresponding pad areas P190 may also have a shape rotated by the first rotation angle θ1. For example, when each of the first to sixth pad patterns 190a to 190f and the pad areas P190 has a square shape, one side of the square may define the first rotation angle θ1 as an acute angle with respect to the second direction Y.

The first pad pitch P1 may be defined as a spacing by which the first to sixth pad patterns 190a to 190f are periodically arranged so as to be spaced from each other. For example, the first pad pitch P1 may be defined as a spacing by which the first to sixth pad patterns 190a to 190f are periodically arranged so as to be spaced from each other in a direction defining the first rotation angle θ1 with respect to the first direction X or the second direction Y. As illustrated in FIG. 5, adjacent ones of the plurality of pad areas P190 may share a boundary surface therebetween with each other. That is, each of the pad areas P190 may define a limit of a range in which corresponding one of the first to sixth pad patterns 190a to 190f is enlarged.

In some embodiments, the first pad pitch P1 of each of the pad areas P190 may be expressed based on Equation 1 as set forth below.

$$P 1 = \sqrt{( CAx * CAy )} \qquad [ Equation 1 ]$$

In the Equation 1, CAx represents the first cell pitch CAx in the first direction X of each of the first to sixth cell areas CA1 to CA6, and CAy represents the second cell pitch CAy in the second direction Y of each of the first to sixth cell areas CA1 to CA6. That is, in a plan view (e.g., in the XY plane) intersecting the third direction Z, an area size (i.e., P1²) of each of the pad areas P190 which has a square shape may be equal to an area size (i.e., CAx*CAy) of each of the cell areas CA.

In addition, the first rotation angle θ1 of each of the pad areas P190 may be expressed based on Equation 2 as set forth below.

$$θ 1 = {sin}^{- 1} ( \frac{CAy}{P 1} ) * ( \frac{180}{π} ) \qquad [ Equation 2 ]$$

In the Equation 2, the first rotation angle θ1 has a unit of degree (°). In addition, in Equation 2, CAy represents the second cell pitch CAy in the second direction Y of each of the first to sixth cell areas CA1 to CA6, and P1 represents the first pad pitch P1 of each of the pad areas P190.

In some embodiments, the first to sixth conductive patterns 120a to 120f and the first to sixth pad patterns 190a to 190f may have a 1:1 correspondence with each other and may be connected to each other. For example, as illustrated in FIG. 6, first to third connection patterns 170a to 170c spaced apart from each other may be connected to and disposed between the first to third conductive patterns 120a to 120c and the first to third pad patterns 190a to 190c. In addition, first via patterns 160 extending in the third direction Z so as to respectively connect the first to third conductive patterns 120a to 120c to the first to third connection patterns 170a to 170c may be formed. In addition, second via patterns 180 extending in the third direction Z so as to respectively connect the first to third connection patterns 170a to 170c to the first to third pad patterns 190a to 190c may be formed. The first conductive pattern 120a may be electrically connected to the first pad pattern 190a by the first connection pattern 170a, the second conductive pattern 120b may be electrically connected to the second pad pattern 190b by the second connection pattern 170b, and the third conductive pattern 120c may be electrically connected to the third pad pattern 190c by the third connection pattern 170c. The size, shape, and arrangement of each of the first to third connection patterns 170a to 170c are only examples, and are not limited to those shown.

In some embodiments, the first to sixth pad patterns 190a to 190f may be arranged in a line along the first direction X. For example, as illustrated in FIG. 5, a straight line connecting centers of the first to sixth pad patterns 190a to 190f to each other may extend in the first direction X. In some embodiments, each of the first to sixth pad patterns 190a to 190f may overlap a plurality of cell areas arranged along the second direction Y. For example, each of the first to third pad patterns 190a to 190c may overlap the first to third cell areas CA1 to CA3 in the third direction Z. The number of the cell areas overlapping each of the first to sixth pad patterns 190a to 190f is only an example, and may vary based on the first pad pitch P1 and the first rotation angle θ1.

In some embodiments, a pair of conductive patterns adjacent to each other in the first direction X among the conductive patterns 120a to 120f may be connected commonly to one unit sense amplifier area SA. For example, the first pad pattern 190a connected to the first conductive pattern 120a and the fourth pad pattern 190d connected to the fourth conductive pattern 120d may be connected commonly to one unit sense amplifier area SA.

The unit sense amplifier area SA may constitute the sense amplifier 30 described above using FIG. 1. For example, the first conductive pattern 120a may be provided as a bit line BL for the first cell area CA1, and the fourth conductive pattern 120d may be provided as a reference bit line/BL for the first cell area CA1. The unit sense amplifier area SA may be included in the peripheral circuit structure PERI described above with reference to FIG. 2. In some embodiments, the unit sense amplifier area SA may overlap a pair of cell areas corresponding thereto (e.g., the first cell area CA 1 and the fourth cell area CA 4) in the third direction Z. For example, a first circuit pitch SAx in the first direction X of the unit sense amplifier area SA may be twice of the first cell pitch CAx. In addition, for example, a second circuit pitch SAy in the second direction Y of the unit sense amplifier area SA may be equal to the second cell pitch CAy.

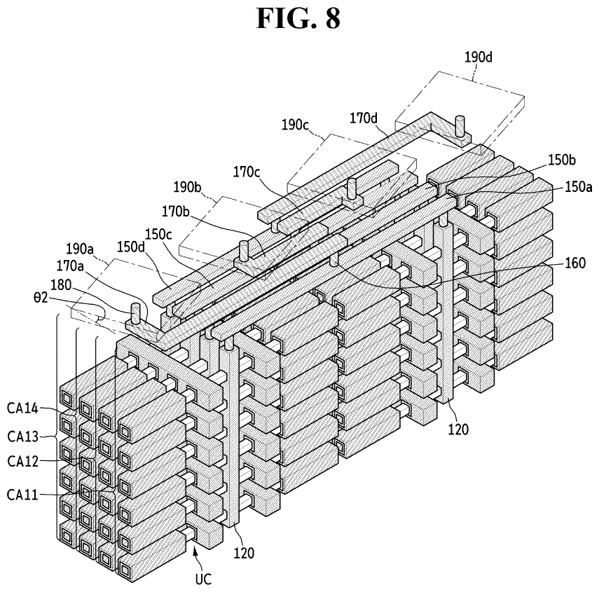

FIG. 7 is an example plan view for illustrating pad patterns of a semiconductor memory device according to some embodiments. FIG. 8 is an example perspective view for illustrating pad patterns of a semiconductor memory device according to some embodiments. For convenience of description, contents duplicative with those described above with reference to FIGS. 1 to 6 will be briefly described or descriptions thereof will be omitted.

Referring to FIGS. 7 and 8, the semiconductor memory device according to some embodiments may include first to 16th cell areas CA11 to CA82, first to eighth strap patterns 150a to 150h, and first to eighth pad patterns 190a to 190h.

The first to fourth cell areas CA11, CA21, CA31, and CA41 may be sequentially arranged along the second direction Y. The fifth to eighth cell areas CA12, CA22, CA32, and CA42 may be sequentially arranged along the second direction Y. The ninth to twelfth cell areas CA51, CA61, CA71, and CA81 may be sequentially arranged along the second direction Y. The 13th to 16th cell areas CA52, CA62, CA72, and CA82 may be sequentially arranged along the second direction Y. The first, fifth, ninth, and thirteenth cell areas CA11, CA12, CA51, and CA52 may be sequentially arranged along the first direction X. The second, sixth, tenth, and fourteenth cell areas CA21, CA22, CA61, and CA62 may be sequentially arranged along the first direction X. The third, seventh, eleventh, and fifteenth cell areas CA31, CA32, CA71, and CA72 may be sequentially arranged along the first direction X. The fourth, eighth, twelfth, and sixteenth cell areas CA41, CA42, CA81, and CA82 may be sequentially arranged along the first direction X.

Each of the first to 16th cell areas CA11 to CA82 may include a corresponding conductive pattern 120. Each of the first to 16th cell areas CA11 to CA82 may correspond to the cell area CA of FIGS. 3 and 4. For example, each of the first to 16th cell areas CA11 to CA82 may include the plurality of unit memory cells UC described above with reference to FIG. 4.

The first to eighth strap patterns 150a to 150h may be formed on corresponding groups of the first to sixteenth cell areas CA11 to CA82 (e.g., adjacent pairs of cell areas CA in the first direction X). Each of the first to eighth strap patterns 150a to 150h may extend in an elongate manner in the first direction X (e.g., may extend lengthwise in the first direction X). In some embodiments, each of the first to eighth strap patterns 150a to 150h may be connected commonly to n conductive patterns 120 (where n is a natural number of 2 or greater) arranged along the first direction X. Accordingly, the number of the conductive patterns 120 and the number of the strap patterns 150a to 150h may have a n:1 correspondence relationship with each other. FIGS. 7 and 8 illustrate that the number of conductive patterns 120 and the number of strap patterns 150a to 150h have a 2:1 correspondence relationship with each other. For example, the first strap pattern 150a may extend in the first direction X so as to connect the conductive pattern 120 of the first cell area CA11 and the conductive pattern 120 of the fifth cell area CA12 to each other.

For example, the fifth strap pattern 150e may extend in the first direction X so as to connect the conductive pattern 120 of the ninth cell area CA51 and the conductive pattern 120 of the thirteenth cell area CA52 to each other. The first to eighth pad patterns 190a to 190h may be formed on the first to eighth strap patterns 150a to 150h. The first to eighth strap patterns 150a to 150h may be interposed between the first to 16th cell areas CA11 to CA82 and the first to eighth pad patterns 190a to 190h in the third direction Z.

The first to eighth pad patterns 190a to 190h may be spaced apart from each other. For example, a plurality of pad areas P190 corresponding to the first to eighth pad patterns 190a to 190h may be defined on the first to 16th cell areas CA11 to CA82. The plurality of pad areas P190 may have a 1:1 correspondence relationship with the first to eighth pad patterns 190a to 190h. The first to eighth pad patterns 190a to 190h may be disposed in corresponding pad areas P190, respectively. In a plan view intersecting the third direction Z (e.g., in the XY plane), each of the pad areas P190 may have an area larger than and a similar shape to an area and a shape of corresponding one of the first to eighth pad patterns 190a to 190h. For example, when each of the first to eighth pad patterns 190a to 190h has a square shape having each side of a second length W2, each of the pad areas P190 may have a square shape having each side of a second pad pitch P2 greater than the second length W2.

In a plan view intersecting the third direction Z (e.g., in the XY plane), each of the first to eighth pad patterns 190a to 190h may have a shape rotated by a predetermined second rotation angle θ2 with respect to the first direction X or the second direction Y. As each of the first to eighth pad patterns 190a to 190h has a shape rotated by the second rotation angle θ2, each of the corresponding pad areas P190 may also have a shape rotated by the second rotation angle θ2. For example, when each of the first to eighth pad patterns 190a to 190h and the pad areas P190 has a square shape, each side of the square may define the second rotation angle θ2 as an acute angle with respect to the second direction Y.

The second pad pitch P2 may be defined as a spacing by which the first to eighth pad patterns 190a to 190h are periodically arranged so as to be spaced from each other. For example, the second pad pitch P2 may be defined as a spacing by which the first to eighth pad patterns 190a to 190h are periodically arranged so as to be spaced from each other in a direction defining the second rotation angle θ2 with respect to the first direction X or the second direction Y. As illustrated in FIG. 7, adjacent ones of the plurality of pad areas P190 may share a boundary surface therebetween with each other. That is, each of the pad areas P190 may define a limit of a range in which the corresponding one of the first to eighth pad patterns 190a to 190h is enlarged.

In some embodiments, the second pad pitch P2 of each of the pad areas P190 may be expressed based on Equation 3 as set forth below.

$$P 2 = \sqrt{( n * CAx * CAy )} \qquad [ Equation 3 ]$$

In the Equation 3, n (where n is a natural number equal to or greater than 2) represents the number of conductive patterns 120 shared by each of the first to eighth strap patterns 150a to 150h, CAx represents the first cell pitch CAx in the first direction X of each of the first to 16th cell areas CA11 to CA82, and CAy represents the second cell pitch CAy in the second direction Y of each of the first to 16th cell areas CA11 to CA82. That is, in a plan view (e.g., in the XY plane) intersecting the third direction Z, an area size (i.e., P2²) of each of the pad areas P190 that has a square shape may be equal to a sum (i.e., n*CAx*Cay) of area sizes of the cell areas shared by each of the first to eighth strap patterns 150a to 150h.

In addition, the second rotation angle θ2 of each of the pad areas P190 may be expressed based on Equation 4 as set forth below.

$$θ 2 = {sin}^{- 1} ( \frac{CAy}{n * P 2} ) * ( \frac{180}{π} ) \qquad [ Equation 4 ]$$

In the Equation 4, the second rotation angle θ2 has a unit of a degree (°). In addition, in the Equation 4, n (where n is a natural number greater than or equal to 2) represents the number of conductive patterns 120 shared by each of the first to eighth strap patterns 150a to 150h, CAy represents the second cell pitch CAy in the second direction Y of each of the first to 16th cell areas CA11 to CA82, and P2 represents the second pad pitch P2 of each of the pad areas P190.

In some embodiments, the first to eighth strap patterns 150a to 150h and the first to eighth pad patterns 190a to 190h may be connected to each other in a 1:1 correspondence relationship with each other. For example, as illustrated in FIG. 8, the first to fourth connection patterns 170a to 170d spaced apart from each other may be connected to and disposed between the first to fourth strap patterns 150a to 150d and the first to fourth pad patterns 190a to 190d. In addition, the first via patterns 160 extending in the third direction Z so as to respectively connect the first to fourth strap patterns 150a to 150d to the first to fourth connection patterns 170a to 170d may be formed. In addition, the second via patterns 180 extending in the third direction Z so as to respectively connect the first to fourth connection patterns 170a to 170d to the first to fourth pad patterns 190a to 190d may be formed. The first conductive pattern 120a may be electrically connected to the first pad pattern 190a via the first connection pattern 170a, the second conductive pattern 120b may be electrically connected to the second pad pattern 190b via the second connection pattern 170b, the third conductive pattern 120c may be electrically connected to the third pad pattern 190c via the third connection pattern 170c, and the fourth conductive pattern 120d may be electrically connected to the fourth pad pattern 190d via the fourth connection pattern 170d. The size, shape, and arrangement of each of the first to fourth connection patterns 170a to 170d are only examples, and are not limited to those shown.

In some embodiments, the first to eighth pad patterns 190a to 190h may be arranged in a line along the first direction X. For example, as illustrated in FIG. 7, a straight line connecting centers of the first to eighth pad patterns 190a to 190h to each other may extend in the first direction X. In some embodiments, each of the first to eighth pad patterns 190a to 190h may overlap a plurality of cell areas arranged along the second direction Y. For example, each of the first and second pad patterns 190a and 190b may overlap the first to fourth cell areas CA11, CA21, CA31, and CA41 in the third direction Z. The number of cell areas overlapping each of the first to eighth pad patterns 190a to 190h is only an example, and may vary according to the second pad pitch P2 and the second rotation angle θ2.

In some embodiments, a pair of the strap patterns adjacent to each other in the first direction X among the strap patterns 150a to 150h may be connected commonly to one unit sense amplifier area SA. For example, the first pad pattern 190a connected to the first strap pattern 150a and the fifth pad pattern 190e connected to the fifth strap pattern 150e may be connected commonly to one unit sense amplifier area SA.

The unit sense amplifier area SA may constitute the sense amplifier 30 described above using FIG. 1. For example, the first strap pattern 150a may be provided as a bit line BL for the first cell area CA11 and the fifth cell area CA12, and the fifth strap pattern 150e may be provided as a reference bit line/BL for the first cell area CA11 and the fifth cell area CA12. The unit sense amplifier area SA may be included in the peripheral circuit structure PERI described above using FIG. 2. In some embodiments, the unit sense amplifier area SA may overlap n pairs of cell areas (e.g., the first cell area CA11, the fifth cell area CA12, the ninth cell area CA51, and the 13th cell area CA52) corresponding thereto (where n is the number of conductive patterns 120 shared by each of the first to eighth strap patterns 150a to 150h) in the third direction Z. For example, the first circuit pitch SAx in the first direction X of the unit sense amplifier area SA may be 2n times of the first cell pitch CAx (where n is the number of conductive patterns 120 shared by each of the first to eighth strap patterns 150a to 150h). In addition, for example, the second circuit pitch SAy in the second direction Y of the unit sense amplifier area SA may be equal to the second cell pitch CAy.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor memory device comprising:
a plurality of cell areas comprising a plurality of conductive patterns, the plurality of cell areas two-dimensionally arranged along a first direction and a second direction intersecting each other, each cell area of the plurality of cell areas including a conductive pattern of the plurality of conductive patterns extending in a third direction intersecting the first direction and the second direction; and
a plurality of pad patterns respectively connected to the plurality of conductive patterns,
wherein in a plan view intersecting the third direction, for the plurality of cell areas, a first cell pitch in the first direction is greater than a second cell pitch in the second direction,
wherein in the plan view, each pad pattern of the plurality of pad patterns has a quadrangle shape including a first side and a second side intersecting each other,
wherein in the plan view, for each pad pattern of the plurality of pad patterns, a length of the first side and a length of the second side are both greater than the second cell pitch, and
wherein in the plan view, for each pad pattern of the plurality of pad patterns, the angle between the first side of the pad pattern and the first direction is an acute angle.

2. The semiconductor memory device of claim 1, wherein in each pad pattern of the plurality of pad patterns the length of the first side and the length of the second side are both smaller than a pad pitch P1 represented by the following Equation 1:
$$P 1 = \sqrt{( CAx * CAy )} \qquad [ Equation 1 ]$$
where in the Equation 1, CAx is the first cell pitch, and CAy is the second cell pitch.

3. The semiconductor memory device of claim 2, wherein for each pad pattern of the plurality of pad patterns the acute angle is represented by the following Equation 2:
$$θ 1 = {sin}^{- 1} ( \frac{CAy}{P 1} ) * ( \frac{180}{π} ) \qquad [ Equation 2 ]$$
where in the Equation 2, θ1 is the acute angle, CAy is the second cell pitch, and P1 is the pad pitch.

4. The semiconductor memory device of claim 1, wherein each pad pattern of the plurality of pad patterns has a square shape in the plan view intersecting the third direction.

5. The semiconductor memory device of claim 1, wherein the first cell pitch is five times the second cell pitch or greater.

6. The semiconductor memory device of claim 1, wherein each cell area of the plurality of cell areas includes a plurality of unit memory cells arranged in the third direction,
wherein each unit memory cell of the plurality of unit memory cells includes:
a semiconductor pattern extending in the first direction and connected to the conductive pattern;
a data storage structure connected to the semiconductor pattern; and
a gate electrode extending in the second direction, the gate electrode intersecting the semiconductor pattern between the conductive pattern and the data storage structure.

7. The semiconductor memory device of claim 6, wherein in each unit memory cell of the plurality of unit memory cells the semiconductor pattern extends in the first direction to extend through the gate electrode.

8. The semiconductor memory device of claim 6, wherein in each unit memory cell of the plurality of unit memory cells the data storage structure includes a first electrode connected to the semiconductor pattern, a second electrode facing the first electrode, and a capacitor dielectric layer between the first electrode and the second electrode.

9. The semiconductor memory device of claim 1, further comprising a peripheral circuit structure overlapping the plurality of cell areas in the third direction.

10. The semiconductor memory device of claim 9, wherein the peripheral circuit structure includes a sense amplifier electrically connected to the plurality of pad patterns.

11. A semiconductor memory device comprising:
a plurality of cell areas two-dimensionally arranged along a first direction and a second direction intersecting each other;
a plurality of strap patterns on the plurality of cell areas, each strap pattern of the plurality of strap patterns extending in the first direction; and
a plurality of pad patterns on the plurality of strap patterns, the plurality of pad patterns respectively connected to the plurality of strap patterns,
wherein each cell area of the plurality of cell areas includes:
a plurality of unit memory cells arranged in a third direction intersecting the first direction and the second direction; and
a conductive pattern extending in the third direction and being connected commonly to the plurality of unit memory cells,
wherein each strap pattern of the plurality of strap patterns connects n conductive patterns arranged along the first direction to each other, where n is a natural number of 2 or greater,
wherein each pad pattern of the plurality of pad patterns has a square shape in a plan view intersecting the third direction, and
wherein for each pad pattern of the plurality of pad patterns, the angle between one side of the pad pattern and the first direction is an acute angle.

12. The semiconductor memory device of claim 11, wherein in the plan view intersecting the third direction, for each pad pattern of the plurality of pad patterns, a length of each side of the pad pattern is smaller than a pad pitch P2 represented by the following Equation 3:
$$P 2 = \sqrt{( n * CAx * CAy )} \qquad [ Equation 3 ]$$
wherein in Equation 3, CAx is a first cell pitch in the first direction of the plurality of cell areas, and CAy is a second cell pitch in the second direction of the plurality of cell areas.

13. The semiconductor memory device of claim 12, wherein for each pad pattern of the plurality of pad patterns, the acute angle is represented by the following Equation 4:
$$θ 2 = {sin}^{- 1} ( \frac{CAy}{n * P 2} ) * ( \frac{180}{π} ) \qquad [ Equation 4 ]$$
where in Equation 4, θ2 is the acute angle, CAy is the second cell pitch, and P2 is the pad pitch.

14. The semiconductor memory device of claim 11, wherein each unit memory cell of the plurality of unit memory cells includes:
a semiconductor pattern extending in the first direction and connected to the conductive pattern;
a data storage structure connected to the semiconductor pattern; and
a gate electrode extending in the second direction, the gate electrode intersecting the semiconductor pattern between the conductive pattern and the data storage structure.

15. The semiconductor memory device of claim 11, further comprising a peripheral circuit structure overlapping the plurality of cell areas in the third direction.

16. A semiconductor memory device comprising:
a first substrate including a first surface and a second surface opposite to each other;
a plurality of cell areas on the first surface, the plurality of cell areas including a plurality of conductive patterns and two-dimensionally arranged along a first direction and a second direction parallel to the first surface and intersecting each other, and each cell area of the plurality of cell areas includes a conductive pattern of the plurality of conductive patterns, the conductive pattern extending in a third direction intersecting the first direction and the second direction;
a plurality of pad patterns on the plurality of cell areas, the plurality of pad patterns respectively connected to the plurality of conductive patterns;
a second substrate including a third surface facing the first surface and a fourth surface opposite to the third surface; and
a peripheral circuit element layer disposed on the third surface,
wherein each cell area of the plurality of cell areas includes a plurality of unit memory cells arranged in the third direction,
wherein each unit memory cell of the plurality of unit memory cells includes:
a semiconductor pattern extending in the first direction and connected to the conductive pattern of the cell area;
a data storage structure connected to the semiconductor pattern; and
a gate electrode extending in the second direction, the gate electrode intersecting the semiconductor pattern between the conductive pattern of the cell area and the data storage structure,
wherein each pad pattern of the plurality of pad patterns has a square shape in a plan view intersecting the third direction, and
wherein for each pad pattern of the plurality of pad patterns, the angle between one side of the pad pattern and the first direction is an acute angle.

17. The semiconductor memory device of claim 16, wherein the plurality of cell areas includes a first cell area and a second cell area arranged in the first direction,
wherein the first cell area includes a first conductive pattern extending in the third direction and being connected commonly to the plurality of unit memory cells of the first cell area,
wherein the second cell area includes a second conductive pattern extending in the third direction and being connected commonly to the plurality of unit memory cells of the second cell area,
wherein the plurality of pad patterns includes a first pad pattern electrically connected to the first conductive pattern and a second pad pattern electrically connected to the second conductive pattern, and
wherein the peripheral circuit element layer includes a unit sense amplifier area overlapping the first cell area and the second cell area in the third direction, and being electrically connected to the first pad pattern and the second pad pattern.

18. The semiconductor memory device of claim 16, wherein the plurality of cell areas includes first to fourth cell areas sequentially arranged in the first direction,
wherein the first to fourth cell areas include first to fourth conductive patterns, respectively, wherein each of the first to fourth conductive patterns extends in the third direction and is connected commonly to the plurality of unit memory cells of a corresponding cell area,
wherein the semiconductor memory device further comprises:
a first strap pattern between the plurality of cell areas and the plurality of pad patterns, the first strap pattern extending in the first direction and connecting the first conductive pattern to the second conductive pattern; and
a second strap pattern between the plurality of cell areas and the plurality of pad patterns, the second strap pattern extending in the first direction and connecting the third conductive pattern to the fourth conductive pattern,
wherein the plurality of pad patterns includes a first pad pattern electrically connected to the first strap pattern and a second pad pattern electrically connected to the second strap pattern, and
wherein the peripheral circuit element layer includes a unit sense amplifier area overlapping the first to fourth cell areas in the third direction and being electrically connected to the first pad pattern and the second pad pattern.

19. The semiconductor memory device of claim 16, wherein the plurality of cell areas includes a first cell area and a second cell area arranged in the second direction,
wherein the first cell area includes a first conductive pattern extending in the third direction and being connected commonly to the plurality of unit memory cells of the first cell area,
wherein the second cell area includes a second conductive pattern extending in the third direction and being connected commonly to the plurality of unit memory cells of the second cell area,
wherein the plurality of pad patterns includes a first pad pattern electrically connected to the first conductive pattern and a second pad pattern electrically connected to the second conductive pattern, and
wherein the first pad pattern and the second pad pattern are arranged in the first direction.

20. The semiconductor memory device of claim 19, wherein each of the first pad pattern and the second pad pattern overlaps the first cell area and the second cell area in the third direction.
